(19) United States
(12) Patent Application Publication
(10) Pub. No.: US 2024/0178164 A1
(43) Pub. Date: May 30, 2024

(54) SENSOR PACKAGE WITH LOW ASPECT RATIO THROUGH SILICON VIA

(71) Applicant: Texas Instruments Incorporated, Dallas, TX (US)

(72) Inventors: Masamitsu Matsuura, Oita (JP); Kengo Aoya, Oita (JP); Daiki Komatsu, Oita (JP); Ko Shibata, Oita (JP)

(21) Appl. No.: 17/994,446

(22) Filed: Nov. 28, 2022

(51) Int. Cl. H01L 23/00; H01L 21/768; H01L 23/48

(52) U.S. Cl. CPC H01L 24/05; H01L 21/76898; H01L 23/481; H01L 24/02; H01L 24/04; H01L 24/13; H01L 24/94; H01L 27/144

(57) ABSTRACT

An electronic device includes a semiconductor substrate having a first conductive routing structure on a first side of the semiconductor substrate, and a low aspect ratio via opening extending from the first side to an opposite second side. The electronic device includes a transparent cover over a portion of the first side and covering the patterned first conductive routing structure, as well as an insulator layer including a photo-imageable material on the second side and along a sidewall of the via opening, and a second conductive routing structure on an outer side of the insulator layer and extending through the via opening and directly contacting a portion of the first conductive routing structure.

### BACKGROUND

Ambient light sensors and CMOS image sensors are electronic devices used to detect light, and often include a wafer chip scale package (WCSP) having a semiconductor die with a sensing area that faces upward on a host printed circuit board (PCB). Through silicon vias (TSVs, also referred to as or through-chip vias) route signals from the top side of the die to solder balls or other signal routings at the bottom of the device to help reduce the package size. An isolation layer on the die backside and semiconductor sidewalls of the TSVs isolates the bottom terminal contacts and is typically made of silicon dioxide (SiO₂) deposited by chemical vapor deposition (CVD). However, the bottom side processing is complicated and costly, due to long processing time to etch through the silicon to form the TSVs and CVD deposition and patterning of the silicon dioxide typically requires multiple photolithography process steps.

### SUMMARY

In one aspect, an electronic device includes a semiconductor substrate having opposite first and second sides, a first conductive routing structure on the first side, and a via opening extending from the first side to the second side. A portion of the first conductive routing structure extends over the via opening and the semiconductor substrate has a thickness distance between the first and second sides of approximately 20 μm or more and less than 150 μm. The electronic device includes a transparent cover, an insulator layer, and a second conductive routing structure. The transparent cover extends on a portion of the first side of the semiconductor substrate and covers the patterned first conductive routing structure. The insulator layer extends on the second side of the semiconductor substrate and along a sidewall of the via opening, and the insulator layer includes a photo-imageable material. The second conductive routing structure extends on an outer side of the insulator layer and through the via opening and directly contacts the portion of the first conductive routing structure.

In another aspect, an electronic device includes a semiconductor substrate having opposite first and second sides, a first conductive routing structure on the first side, and a via opening extending from the first side to the second side. A portion of the first conductive routing structure extends over the via opening. The electronic device includes a transparent cover, an insulator layer, and a second conductive routing structure. The transparent cover extends on a portion of the first side of the semiconductor substrate and covers the patterned first conductive routing structure. The insulator layer extends on the second side of the semiconductor substrate and along a sidewall of the via opening and the insulator layer includes a photo-imageable material. The second conductive routing structure extends on an outer side of the insulator layer and through the via opening and directly contacts the portion of the first conductive routing structure.

In a further aspect, a method of fabricating an electronic device includes forming a patterned first conductive routing structure on a first side of a semiconductor substrate, attaching a transparent cover over a portion of the first side of the semiconductor substrate, the transparent cover covering the patterned first conductive routing structure, grinding a second side of the semiconductor substrate to reduce a thickness distance between the first and second sides, forming a via opening extending from the first side of the semiconductor substrate to the second side of the semiconductor substrate, a portion of the first conductive routing structure extending over the via opening, forming an insulator layer on the second side of the semiconductor substrate and along a sidewall of the via opening, and forming a second conductive routing structure on an outer side of the insulator layer, the second conductive routing structure extending through the via opening and directly contacting the portion of the first conductive routing structure.

### BRIEF DESCRIPTION OF THE DRAWINGS

FIG. 1 is a top perspective view of a sensor electronic device.

FIG. 1A is a bottom perspective view of the electronic device of FIG. 1.

FIG. 1B is a partial sectional side elevation view of the electronic device taken along line 1B-1B of FIG. 1.

FIG. 2 is a flow diagram of a method of fabricating an electronic device.

FIGS. 3-16 are partial sectional side elevation views of the electronic device of FIGS. 1-1B undergoing fabrication processing according to the method of FIG. 2.

FIG. 17 is a partial sectional side elevation view of another electronic device.

FIG. 18 is a partial sectional side elevation view of a further electronic device.

FIG. 19 is a sectional side elevation view of a further electronic device.

### DETAILED DESCRIPTION

In the drawings, like reference numerals refer to like elements throughout, and the various features are not necessarily drawn to scale. Also, the term “couple” or “couples” includes indirect or direct electrical or mechanical connection or combinations thereof. For example, if a first device couples to or is coupled with a second device, that connection may be through a direct electrical connection, or through an indirect electrical connection via one or more intervening devices and connections. One or more operational characteristics of various circuits, systems and/or components are hereinafter described in the context of functions which in some cases result from configuration and/or interconnection of various structures when circuitry is powered and operating. Unless otherwise stated, “about,” “approximately.” or “substantially” preceding a value means+/−10 percent of the stated value.

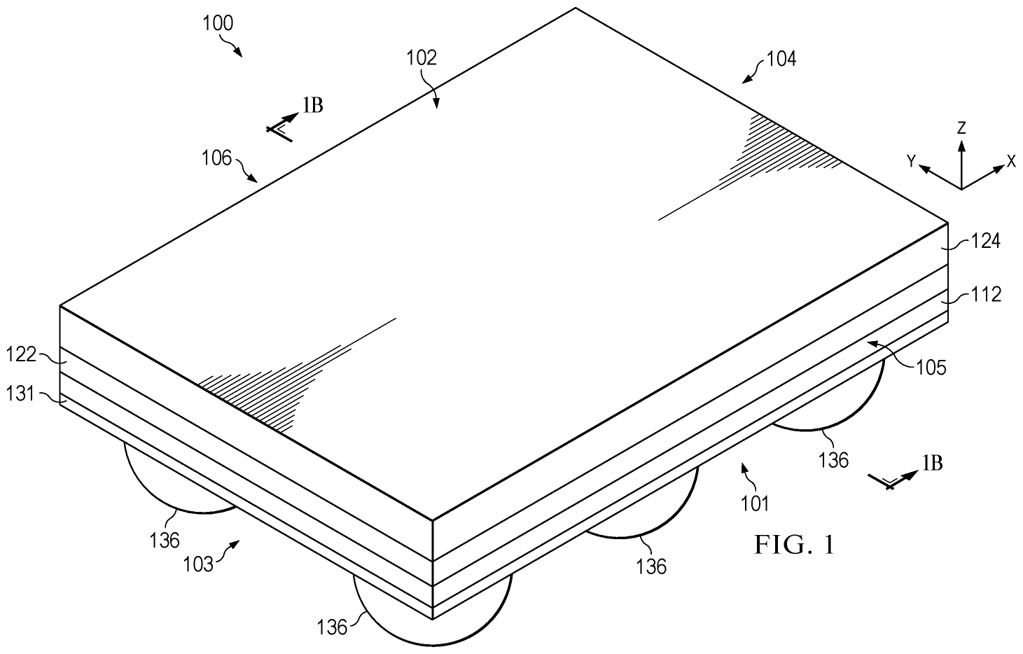

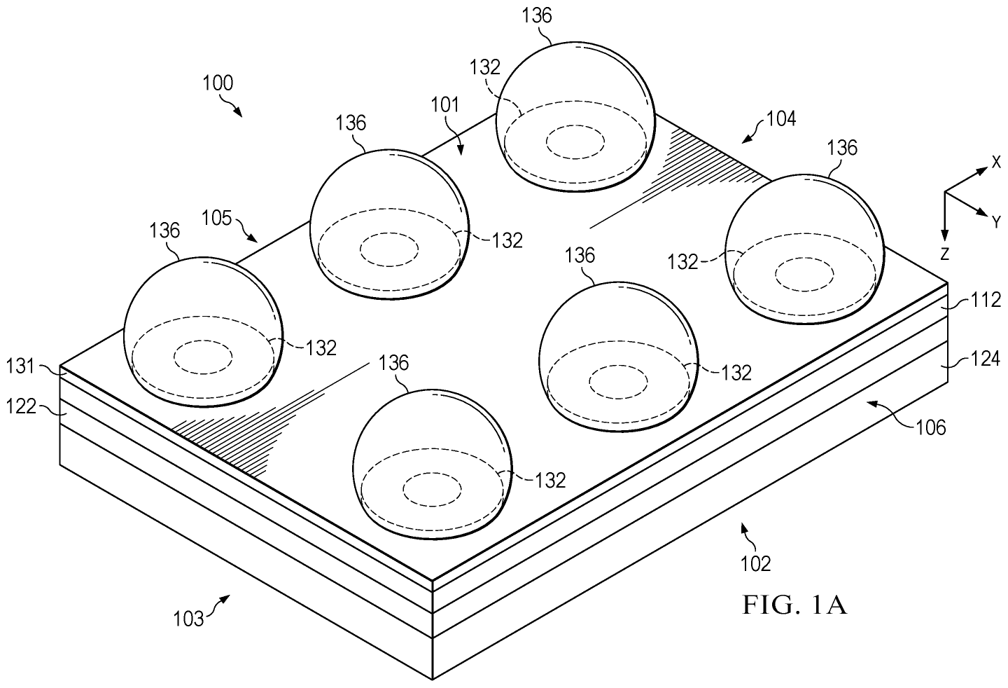

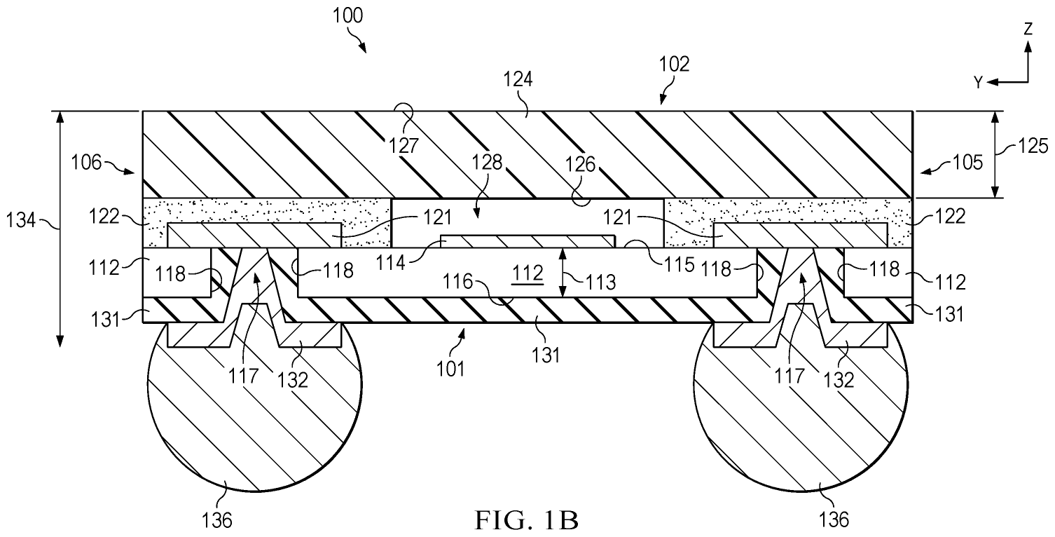

FIGS. 1-1B illustrate an electronic device 100 with a small form factor. FIGS. 1 and 1A show respective top and bottom perspective views and FIG. 1B shows a sectional side view of the electronic device 100 taken along line 1B-1B of FIG. 1.

The electronic device 100 has a generally rectangular shape that includes opposite first and second (e.g., bottom and top) sides 101 and 102, respectively, and lateral third, fourth, fifth, and sixth sides 103, 104, 105, and 106, respectively. In one example, the electronic device 100 has a WCSP package structure. The electronic device 100 is shown in FIGS. 1-1B in an example position or orientation in a three-dimensional space with a first direction X, a perpendicular (orthogonal) second direction Y, and a third direction Z that is perpendicular (orthogonal) to the respective first and second directions X and Y, and structures or features along any two of these respective directions are orthogonal to one another. In the illustrated orientation, the respective first and second sides 101 and 102 are spaced apart from one another along the third direction Z, the respective third and fourth sides 103 and 104 are spaced apart from one another along the first direction X, and the respective fifth and sixth sides 105 and 106 are spaced apart from one another along the second direction Y.

The electronic device 100 includes a thin semiconductor substrate 112, such as a die that is or includes silicon or other suitable semiconductor material, with low aspect ratio through silicon vias to facilitate cost effective insulator formation, for example, using photo-imageable material by spin coating in certain implementations. In one example, the semiconductor substrate 112 has a thickness distance 113 that is less than 150 μm between the respective first and second sides 115 and 116, where larger values can make the subsequent TSV formation more difficult and/or more expensive. In this or another example, the semiconductor thickness distance 113 is approximately 20 μm or more, and smaller values can be difficult to manufacture.

As shown in FIG. 1B, the semiconductor substrate 112 has an optional sensing area 114 exposed along an upper first side 115 of the semiconductor substrate 112. The semiconductor substrate 112 has an opposite (e.g., lower) second side 116. In one example, the sensing area 114 is sensitive to light and internal circuitry of the semiconductor substrate 112 provides a light sensor with external terminal connections to interface the light sensor to a host PCB. The sensing area 114 can be slightly raised from the first side 115 of the semiconductor substrate 112 as shown in FIG. 1B, or the sensing area 114 can be approximately flush with the first side 115 of the semiconductor substrate 112 in other implementations. In another example, the sensing area 114 is omitted.

The semiconductor substrate 112 has low aspect ratio via openings 117 that individually extend from the first side 115 of the semiconductor substrate 112 to the second side 116 of the semiconductor substrate 112. The via openings 117 include at least one sidewall 118. In one example, the via openings 117 have a curved shape, such as a circle or oval, although not a requirement of all possible implementations.

First conductive routing structures 121 extend on the first side 115 of the semiconductor substrate 112 and the first conductive routing structures 121 are laterally spaced apart from the sensing area 114 (e.g., along the first direction X as shown in FIG. 1B). A portion of the individual first conductive routing structures 121 extends over the associated via opening 117 to allow bottom side electrical connection to circuitry or components of the semiconductor substrate 112. In one example, the first conductive routing structures 121 are or include copper.

Wafer bond material 122 extends on all or portions of the first side 115 of the semiconductor die 112. A transparent cover 124 extends over a portion of the first side 115 of the semiconductor substrate 112 and provides the top or second side 102 of the electronic device 100. The transparent cover 124 covers the sensing area 114 and the patterned first conductive routing structure 121 and allows light to pass from the second side 102 to the sensing area 114 of the semiconductor substrate 112. In one example, the transparent cover 124 is or includes glass. The transparent cover 124 has a thickness dimension 125 along the third direction Z between a lower or bottom side 126 and an upper or top side 127.

The wafer bond material 122 in one example is a cured adhesive that bonds the transparent cover 124 to the first side 115 of the semiconductor substrate 112. In the illustrated example of FIG. 1B, the wafer bond material 122 is patterned to extend over the first conductive routing structures 121 and portions of the first side 115 of the semiconductor substrate 112, while not extending over the sensing area 114. This example allows use of semi-transparent or non-transparent wafer bond material 122 while allowing light to enter the sensing area 114 from the transparent cover 124. In another example, wafer bond material 122 is at least partially transparent. In one example, the wafer bond material 122 is not patterned, at least partially transparent, and extends over any included sensing area 114. In the illustrated example, the wafer bond material 122 is patterned and leaves a gap 128 between the sensing area 114 and the bottom side 126 of the transparent cover 124 as shown in FIG. 1B.

As further shown in FIGS. 1A and 1B, the electronic device 100 includes an insulator layer 131 on the second side 116 of the semiconductor substrate 112 and along the sidewalls 118 of the via openings 117. In one example, the insulator layer 131 includes a photo-imageable material. In one example, the insulator layer 131 is or includes polyimide material. In another example, the insulator layer 131 is or includes polybenzoxazole (PBO) material. In another example, the insulator layer 131 is or includes a solder mask material. In one example, the insulator layer 131 is a single layer. In another implementation, the insulator layer 131 is a multilayer structure, for example, including a second photo-imageable material,

The electronic device 100 also includes second conductive routing structures 132 on an outer side of the insulator layer 131, as shown in FIGS. 1A and 1B. The second conductive routing structures 132 extend through the via opening 117 and directly contact a portion of a respective first conductive routing structure 121. In one implementation, the first and second conductive routing structures 121 and 132 are or include copper. In this or another example, the first and second conductive routing structures 121 and 132 are formed by electroplating, for example, using associated redistribution layer (RDL) or bonding over active circuit (BOAC) processes. The thickness of the second conductive routing structures 132 on the insulator layer 131 sets a final device height 134 (FIG. 1B) for mounting the electronic device 100 on a host system PCB (not shown).

As shown in FIGS. 1A and 1B, the electronic device 100 in one example also includes solder structures 136 attached to respective second conductive routing structures 132 to allow the electronic device 100 to be soldered to a host PCB. The solder structures 136 extend outward (e.g., downward) along the third direction Z from the bottom side 101 of the electronic device 100. In the illustrated example, the solder structures 136 are solder balls with a somewhat spherical shape as shown in FIGS. 1A and 1B. In another example, the solder structure 136 are printed solder features (not shown) of any suitable shape and attached to respective ones of the second conductive routing structures 132.

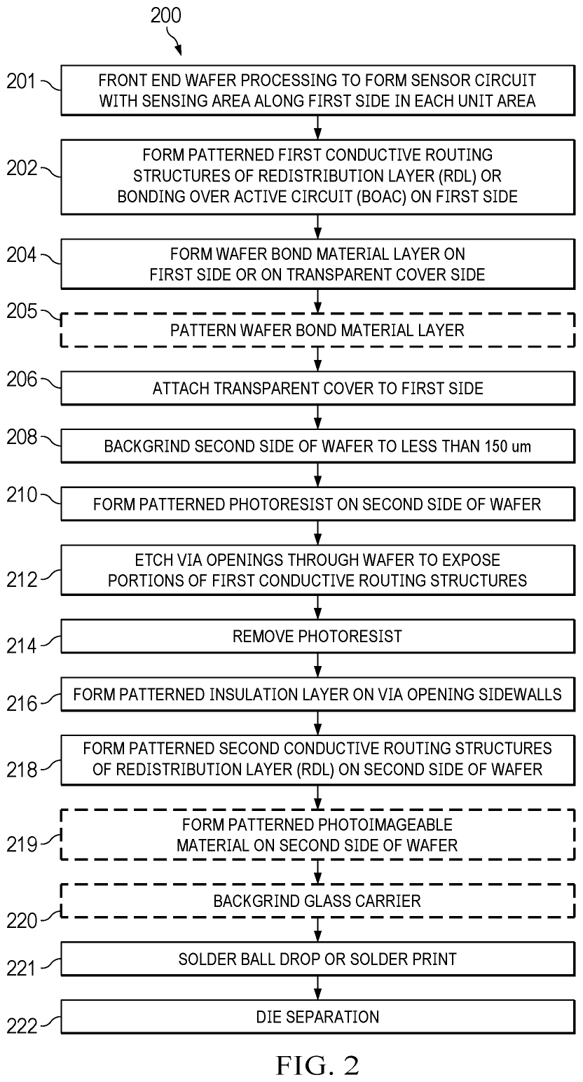

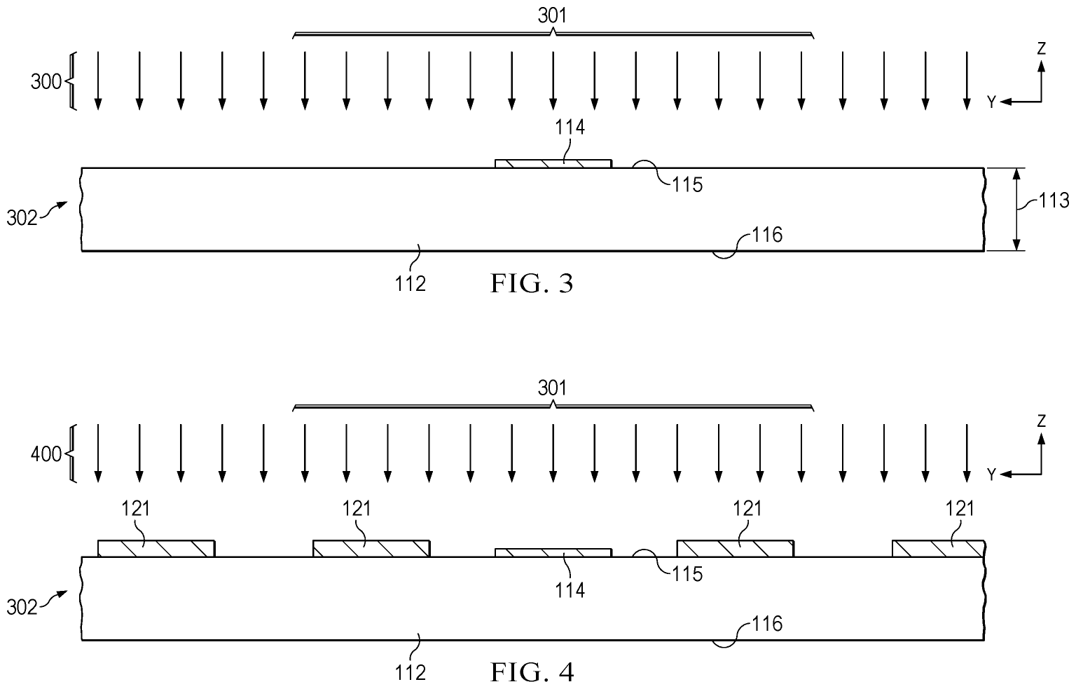

Referring now to FIGS. 2-16, FIG. 2 shows a method 200 of fabricating an electronic device and FIGS. 3-16 show the electronic device 100 of FIGS. 1-1B undergoing fabrication processing according to the method 200. The method 200 in one example includes front end wafer processing at 201 in FIG. 2 to form circuitry, such as a light sensing circuit with a sensing area along a top or first side in each of a plurality of unit areas of the starting wafer. FIG. 3 shows one example, in which a front end wafer fabrication process 300 is performed that forms light sensing circuitry (e.g., transistors, diodes, etc., not shown) in a unit area 301 of a starting semiconductor wafer 302, also referred to herein as a semiconductor substrate. In the illustrated example, the wafer 302 includes the prospective semiconductor substrates 112 of the ultimately formed packaged electronic devices 100, which are separated after certain of the described process steps, and the following discussion refers to the wafer 302 with respect to the prospective semiconductor substrates 112.

The method 200 continues at 202 in FIG. 2 with forming patterned first conductive routing structures on a first side of the wafer. FIG. 4 shows one example, in which a redistribution layer (RDL) or bonding on active circuit (BOAC) process 400 is performed that forms the patterned first conductive routing structures 121 in each unit region 301 on the first side 115 of the wafer 302. In one example, a titanium and a copper seed layer are deposited (e.g., by sputtering or other deposition technique) on the first side 115 and patterned to extend on areas spaced apart from the respective sensing areas 114, followed by electroplating to form the first conductive routing structures 121 in each unit region 301, and removal of any remaining portions of the seed layer at 202 in FIG. 2.

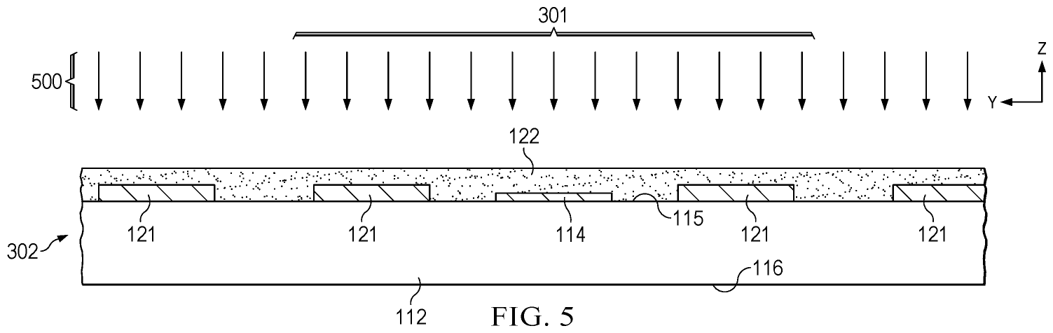

At 204 in FIG. 2, the method 200 continues with forming a wafer bond material layer on the first side of the wafer. FIG. 5 shows one example, in which a coating process 500 is performed that coats the wafer bond material 122 as a layer on the first side 115 of the wafer 302, covering the patterned first conductive routing structures 121 and any included sensing area 114 in each unit region 301.

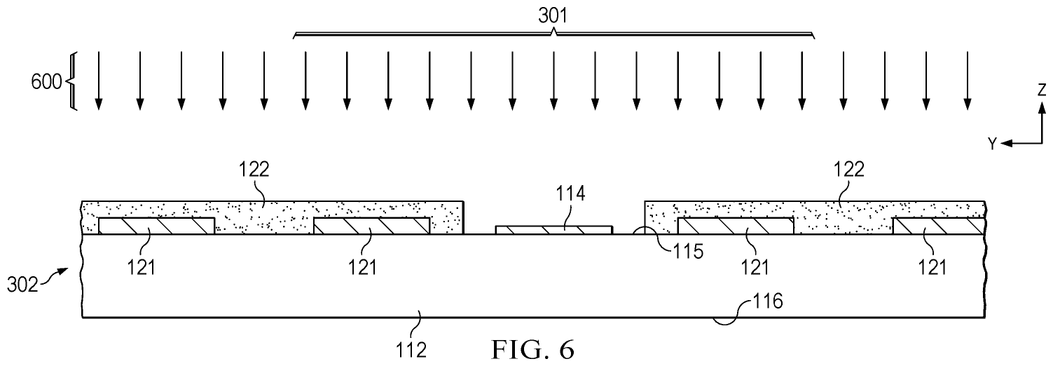

In one implementation, the method 200 includes optionally patterning the wafer bond material 122 at 205. FIG. 6 shows one example, in which an exposure step is performed using a stepper and a development process 600 is performed that removes the wafer bond material 122 above the sensing areas 114. In another implementation, for example using transparent wafer bond material 122, the patterning at 205 is omitted.

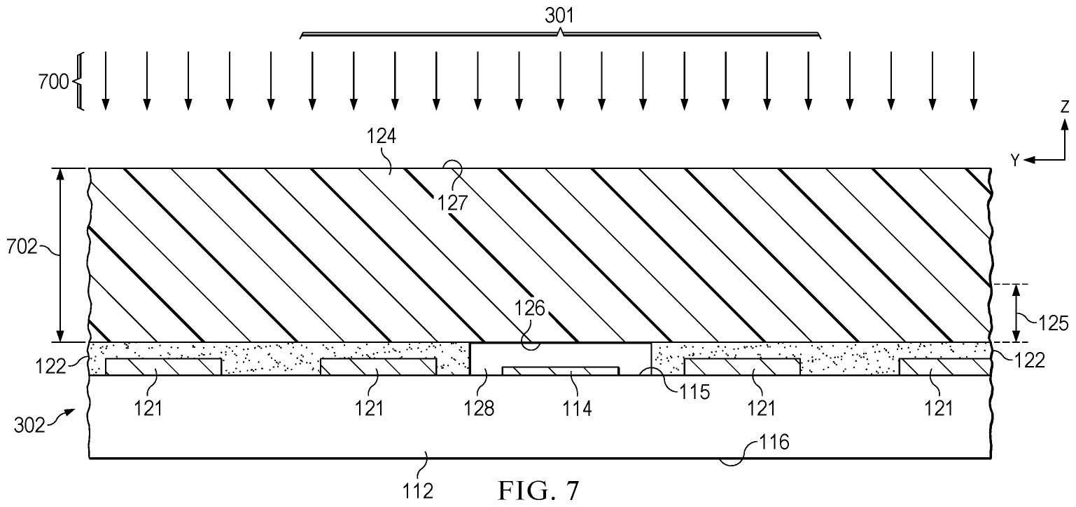

At 206 in FIG. 2, a glass carrier or other suitable transparent cover is attached. FIG. 7 shows one example, in which an attachment process 700 is performed that attaches the transparent cover 124 on the wafer bond material 112 over the first side 115 of the wafer 302 such that the transparent cover 112 covers the sensing areas 114 and the patterned first conductive routing structures 121 in each unit area 301. As shown in FIG. 7, in one example, the attached transparent cover 124 has a starting thickness 702 that is significantly greater than the final thickness dimension 125 along the third direction Z between the lower or bottom side 126 and the upper or top side 127 of the transparent cover 124 described above in connection with FIG. 1B. In the illustrated example, the process 700 adheres the attached transparent cover 124 to the wafer 302 by the wafer bond material 122 and may include the gaps 128 in the case of a patterned wafer bond material 122 implementation as shown in FIG. 7. In one example, the attachment process 700 installs a single transparent cover 124 on the wafer bond material 122 to cover the entire processed wafer, as shown in FIG. 7. In another example, automated pick and place equipment (not shown) attaches individual transparent covers 124 for each unit area 301 (not shown). In these or other examples, the attachment process 700 includes a curing step to cure the wafer bond material 122, for example, using heat, UV exposure, or other suitable technique.

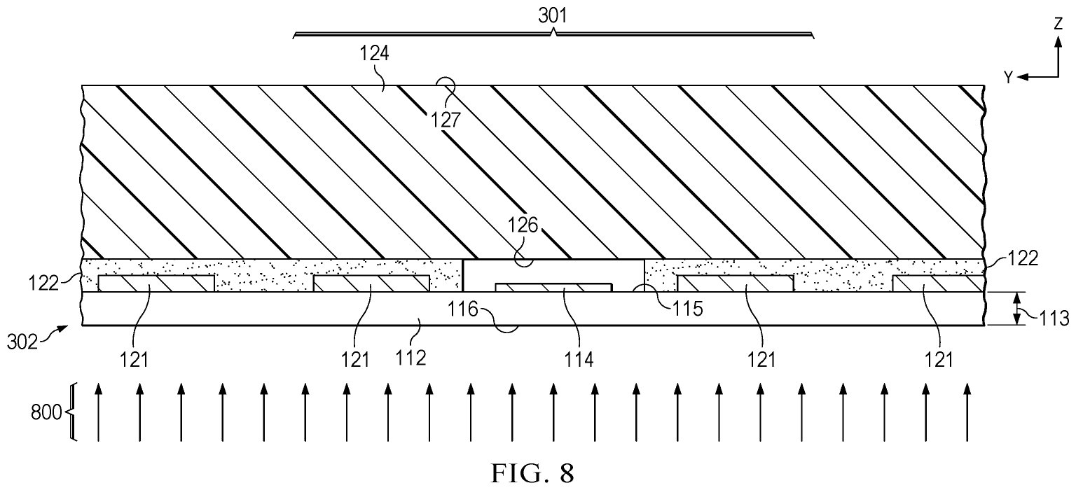

The method 200 continues at 208 with grinding the second (e.g., back or bottom) side of the wafer 302. FIG. 8 shows one example, in which a grinding process 800 is performed that removes material from the second side 116 of the wafer 302, for example, by mechanical grinding, chemical mechanical polishing (CMP) or other suitable material removal technique. In one example, the grinding process 800 reduces the thickness distance 113 between the first and second sides 115 and 116 below 150 μm, for example, to approximately 20 μm or more and less than 150 μm. This reduces the aspect ratios of the ultimately formed via openings (e.g., 117 in FIG. 1B above), which in turn facilitates spin coating processing and simplified patterning in forming the insulator layer 131 using photo-imageable material to help reduce manufacturing time, complexity and cost. Moreover, the grinding process 800 helps reduce the overall finished device height (e.g., the final device height 134 shown in FIG. 1B) to accommodate high density circuit board and system designs using the finished electronic device 100.

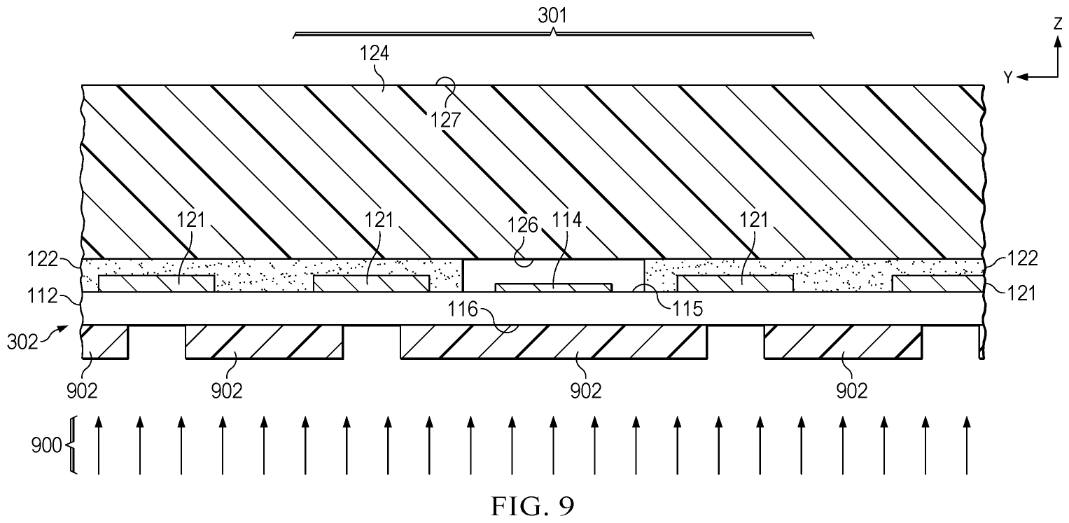

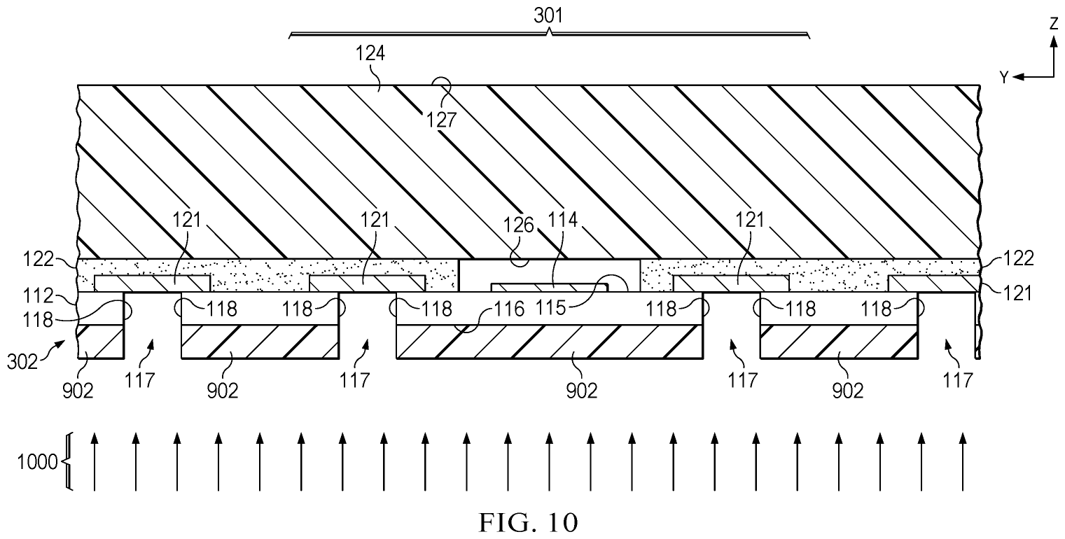

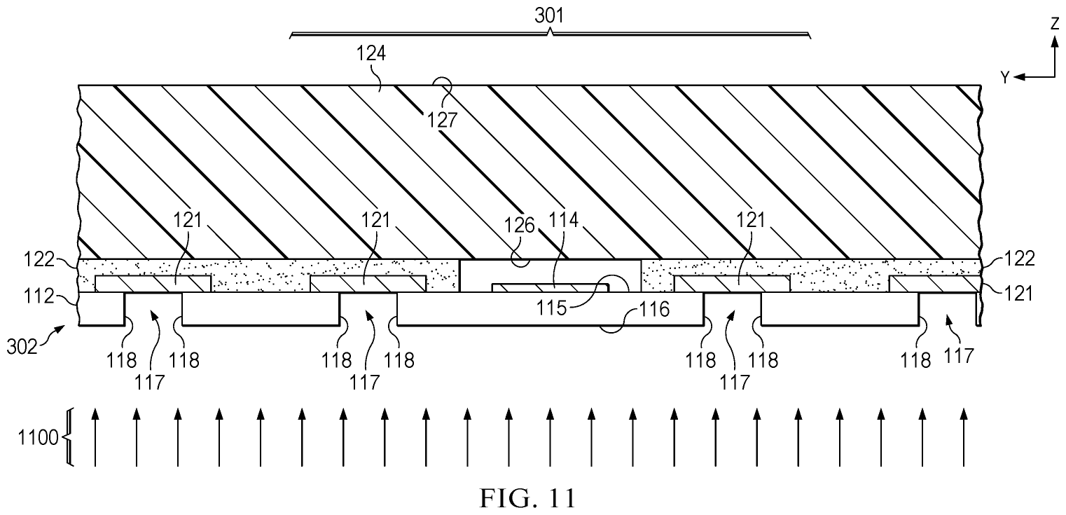

The method 200 in FIG. 2 continues at 210, 212 and 214 with through silicon via (TSV) formation. At 210, a patterned photo resist is formed on the bottom side of the wafer. FIG. 9 shows one example, in which a process 900 is performed that forms a patterned photo resist 902 on the second side 116 of the wafer 302, including depositing a resist material, exposing select portions of the resist to light, and removing the exposed portions to provide the patterned photo resist 902 shown in FIG. 9. At 212 in FIG. 2, via openings are etched through the exposed portions of the wafer. FIG. 10 shows one example, in which an etch process 1000 is performed using the patterned resist 902 as an etch mask. The etch process 1000 forms the via openings 117 that extending from the first side 115 of the wafer 302 to the second side 116 of the wafer 302. As shown in FIG. 10, moreover, the etch process 1000 extends the via openings to expose a portion of the respective first conductive routing structures 121 in the respective via openings 117. At 214 in FIG. 2, the patterned resist is removed, for example, by a stripping process 1100 shown in FIG. 11.

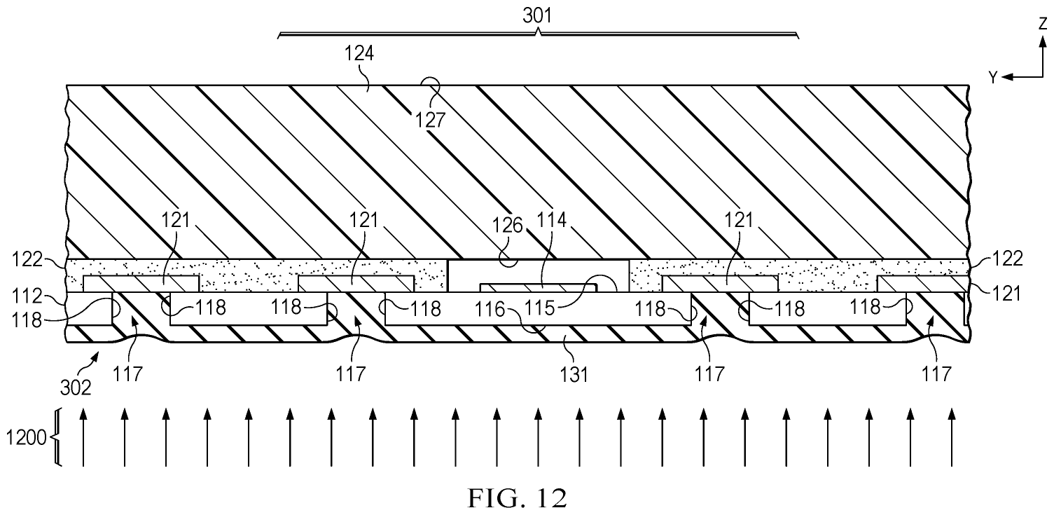

At 216 in FIG. 2, the method 200 continues with forming a patterned insulator layer on the second side 116 of the via sidewalls and the bottom side of the wafer. FIG. 12 shows one example, in which a deposition process 1200 is performed that forms the insulator layer 131 on the second side 116 of the semiconductor substrate 112 and along the sidewalls 118 of the via openings 117 using any suitable material deposition techniques and equipment. The deposited insulator layer 131 may extend onto and cover the exposed portions of the first conductive routing structures 121 in the respective via openings 117, although not required in all implementations.

Sidewall coverage is advantageous to insulate the semiconductor material of the wafer 302 from subsequently formed conductive RDL or BOAC metal inside the via openings 117. Continued exposure of portions of the first conductive routing structures 121 in the respective via openings 117 may mitigate the need for a patterning step before metal formation to form the TSVs, in which case the spin coat deposition at 216 provides a patterned insulation layer 131 without further processing time and expense.

In one example, the deposition process 1200 includes spin coating a photo-imageable (e.g., photosensitive definable material) material on the second side 116 of the semiconductor substrate 112 and along the sidewall 118 of the via opening 117. In this or another example, the deposited photo-imageable material 131 includes polyimide material. In the above or another example, the deposited photo-imageable material 131 includes polybenzoxazole (PBO) material. In the above or another example, the deposited material 131 includes a solder mask material. One example spin coating process includes dispensing photo-imageable material, such as a resin fluid onto the wafer surface, high speed spinning or rotation of the wafer to thin the fluid, and a drying step to eliminate excess solvents from the resulting film. Different implementations can include static dispensing or dynamic dispensing.

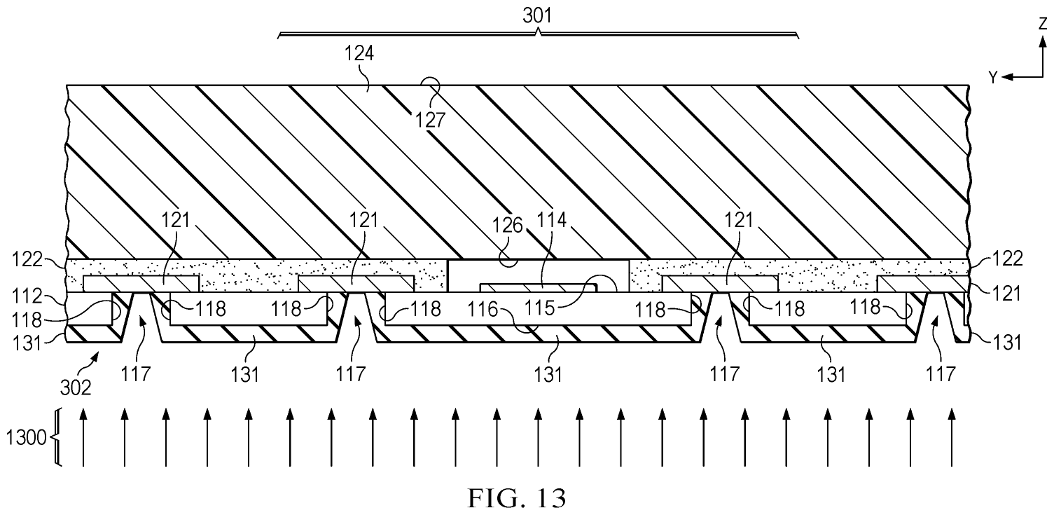

In one example, a patterning step is performed at 216 to expose portions of the first conductive routing structures 121 in the respective via openings 117. FIG. 13 shows one example, in which a patterning process 1300 is performed that patterns the photo-imageable material 131 to expose a portion of the patterned first conductive routing structures 121 in the respective via openings 117. In one implementation, the patterning process 1300 includes light exposure or other photo exposure process. In one example, a photosensitive definable material layer 131 is deposited at 216 such as spin coating or other formation, and the patterning process 1300 includes exposure of portions of the layer 131 to light for development. In another implementation, a coating is formed of a solution on the layer at 216, and solvent is evaporated from the coating. In this implementation, a positive photoresist is applied over the coating and is exposed to a pattern of light by the patterning process 1300, and the exposed portion of the photoresist is removed as well as the exposed portions of the polyamic acid coating thereunder, followed by removal of the remaining photoresist, and the polyamic acid coating is imidized to leave a polyimide patterned insulation layer 131.

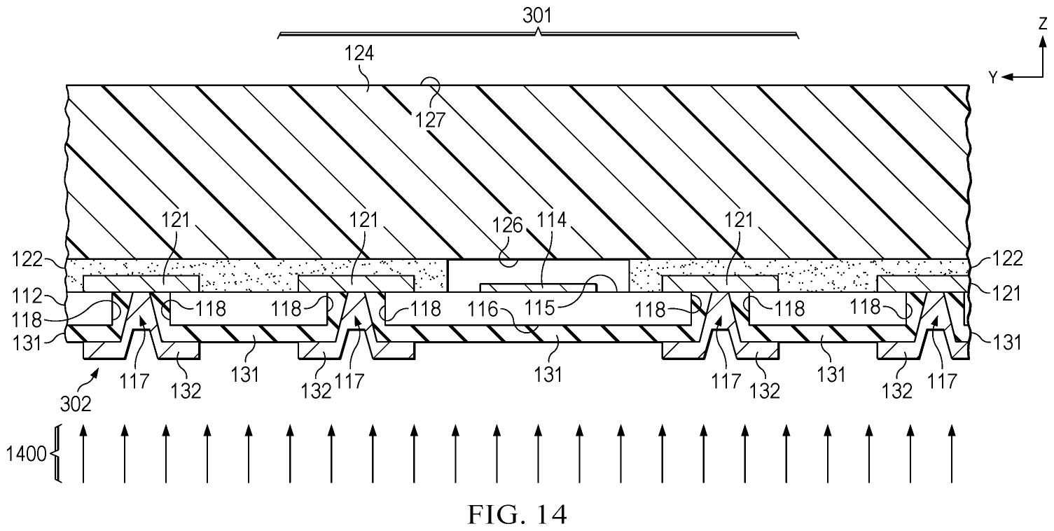

At 218 in FIG. 2, the patterned second conductive routing features are formed on the bottom side of the wafer and on the patterned insulation layer 131 in the via openings 117 to contact the portions of the first conductive routing structures 121 in the respective via openings 117. FIG. 14 shows one example for an RDL implementation, in which a process 1400 is performed that forms the second conductive routing structures 132 on the outer side of the insulator layer 131 so that the second conductive routing structures 132 extend through the respective via opening 117 and directly contact the exposed portion of the respective first conductive routing structure 121.

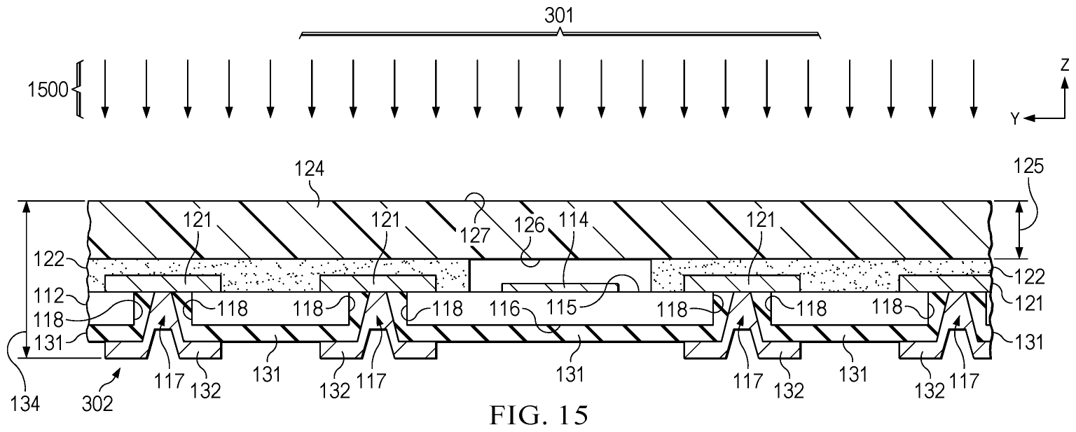

The method 200 in one example includes optional formation of a patterned photo-imageable material on the second side of the wafer at 219 in FIG. 2, for example, as a second layer of a multilayer insulator 131. In another example, the material formation at 219 is omitted. The method 200 in one example includes optional grinding of the transparent cover at 220 in FIG. 2. FIG. 15 shows one example, in which a second grinding process 1500 is performed that removes material from the top side 127 of the transparent cover 124 to reduce the transparent cover 124 thickness distance 125 from its original starting thickness (e.g., starting thickness distance 702 in FIG. 7 above). In another implementation, the grinding of the transparent cover at 220 is omitted. Implementations that include the grinding at 220 advantageously allow case of handling the thicker transparent cover at 220 during attachment at 206, particularly for attachment of a single transparent cover at 220 over the entire wafer 302, while helping to reduce the overall finished device height (e.g., the final device height 134 in FIG. 1B above) to accommodate high density circuit board and system designs using the finished electronic device 100.

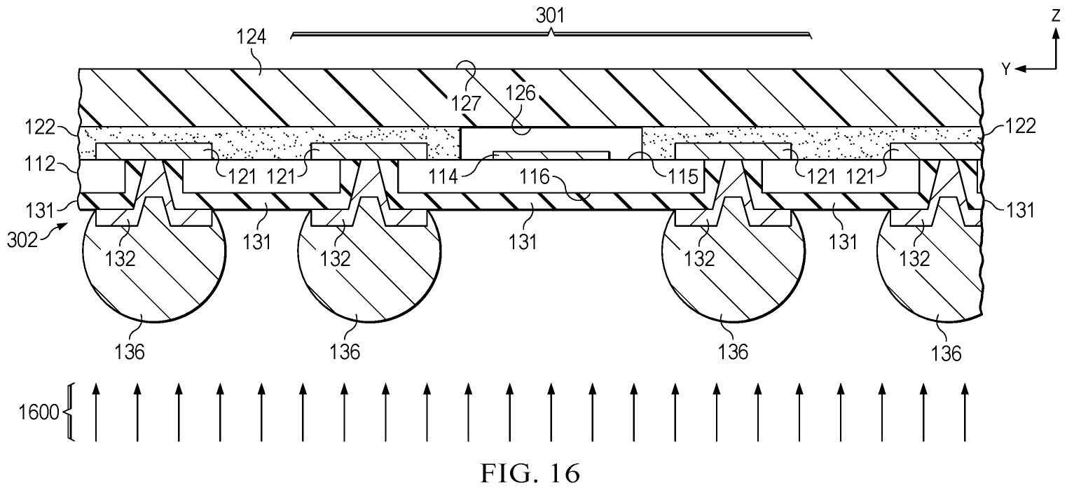

The method 200 in FIG. 2 also includes optional solder ball drop or solder print operations at 221. FIG. 16 shows one example, in which a solder ball drop process 1600 is performed that forms the generally spherical solder structures 136 (e.g., solder balls) on the second conductive routing structure 132, with the solder structures 136 extending outward from the bottom or first side 101 of the electronic device 100.

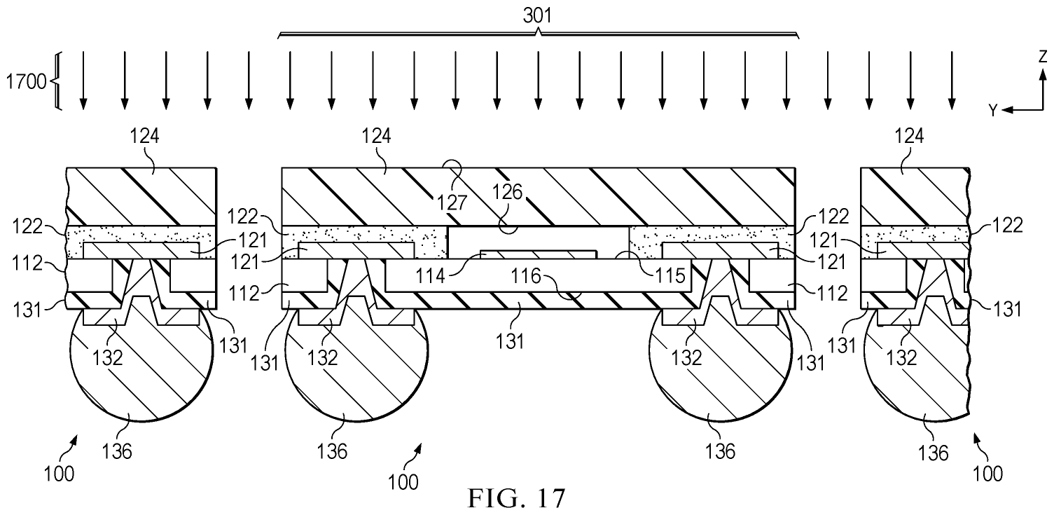

At 222 in FIG. 2, the method 200 further includes device or die separation. FIG. 17 shows one example, in which a cutting process 1700 is performed that cuts the starting wafer along boundaries between rows and columns of unit areas 301, for example, using saws, laser cutting, chemical etching or combinations thereof. The cutting process 1700 separates multiple instances of the finished electronic device 100 from the starting wafer.

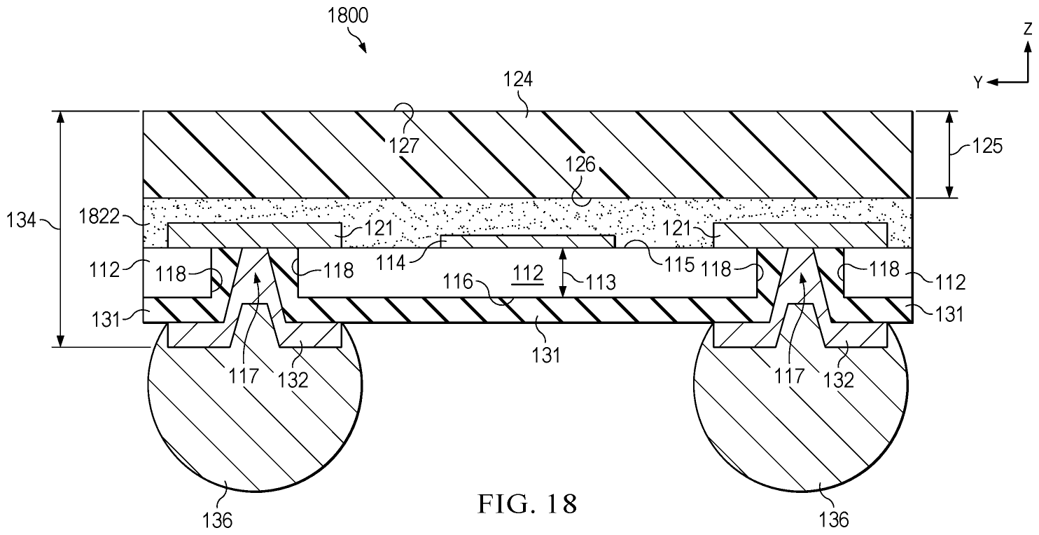

FIG. 18 shows a sectional side view of another example electronic device 1800 with low aspect ratio through silicon vias to facilitate cost effective insulator formation, for example, using photoimageable material by spin coating in certain implementations. The electronic device 100 has structures and features 112-118, 121, 124-127, 131, 132, 134, and 136 as described above in connection with FIGS. 1-1B. In this example, the electronic device 1800 includes a transparent or substantially transparent wafer bond material 1822 that is not patterned (e.g., the wafer bond material patterning at 205 in FIG. 2 is omitted). The wafer bond material 1822 in this example extends over the sensing area 114 of the semiconductor substrate 112 as well as the first conductive routing structures 121 and portions of the first side 115 of the semiconductor substrate 112.

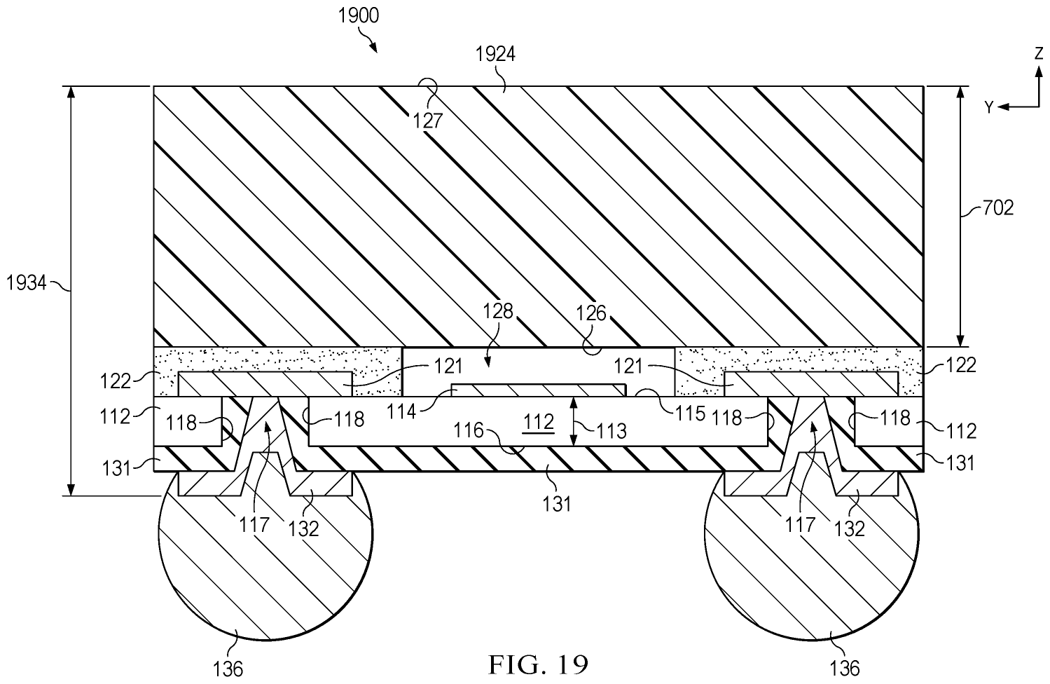

FIG. 19 shows a sectional side view of a further electronic device example 1900 with low aspect ratio through silicon vias. The electronic device 1900 includes structures and features 112-118, 121, 122, 126-128, 131, 132, and 136 as described above in connection with FIGS. 1-1B. In this example, the wafer bond material 122 is patterned and may be transparent or even non-transparent. In another implementation, a transparent wafer bond material (e.g., 1822 in FIG. 18) and need not be patterned. The electronic device 1900 of FIG. 19 has a thicker transparent cover 1924 that extends over a portion of the first side 115 of the semiconductor substrate 112 and provides the top or second side 102 of the electronic device 1900. The device 1900 has a larger device height dimension 1934 than the electronic device 100 and 1800 described above. The transparent cover 1924 covers the sensing area 114 and the patterned first conductive routing structure 121 and allows light to pass from the second side 102 to the sensing area 114 of the semiconductor substrate 112. In one example, the transparent cover 124 is or includes glass. The transparent cover 124 has a thickness dimension 125 along the third direction Z between a lower or bottom side 126 and an upper or top side 127. In this example, the transparent cover 124 has a thickness 702 along the third direction Z between the bottom and top sides 126 and 127 thereof, for example, corresponding to the starting thickness described above in connection with FIG. 7. In one implementation, the second backgrinding operations at 219 in FIG. 2 are omitted in fabricating the electronic device 1900 of FIG. 19.

Unlike higher aspect ratio TVS devices, the described electronic device examples 100, 1800 and 1900 provide low profile device shapes and smaller device height dimensions, along with manufacturing cost savings. Since the example semiconductor substrate 112 or wafer 302 is background to less than 150 μm before TVS formation, the etching time to form the via openings 117 is significantly less than that required to form an opening through a thicker semiconductor wafer, such as 200 to 300 μm. In addition, the lower aspect ratio of the via openings 117 facilitates the cost effective spin coating deposition of the insulator layer 131 using a photo-imageable material that can be patterned without adding an extra mask to the manufacturing process. This saves further cost and manufacturing time compared to CVD or other slower deposition processes used to fill higher aspect ratio TSV openings with SiO₂. The combination in certain examples of a top facing light sensing area 114 with bottom side TSVs for electrical terminal connections to a host PCB allows top side optical light sensing without the need for a hole through the host PCB while providing the compact form factor benefits of wafer chip scale packages using redistribution layer or BOAC signal routing and interconnection technologies.

Modifications are possible in the described examples, and other implementations are possible, within the scope of the claims.

What is claimed is:

1. An electronic device, comprising:
a semiconductor substrate having: opposite first and second sides, a first conductive routing structure on the first side of the semiconductor substrate, and a via opening extending from the first side of the semiconductor substrate to the second side of the semiconductor substrate, a portion of the first conductive routing structure extending over the via opening, the semiconductor substrate having a thickness distance between the first and second sides of approximately 20 μm or more and less than 150 μm;
a transparent cover over a portion of the first side of the semiconductor substrate, the transparent cover covering the patterned first conductive routing structure;
an insulator layer on the second side of the semiconductor substrate and along a sidewall of the via opening, the insulator layer including a photo-imageable material; and
a second conductive routing structure on an outer side of the insulator layer, the second conductive routing structure extending through the via opening and directly contacting the portion of the first conductive routing structure.

2. The electronic device of claim 1, wherein the first and second conductive routing structures include copper.

3. The electronic device of claim 1, wherein the transparent cover includes glass.

4. The electronic device of claim 1, wherein the insulator layer includes polyimide material.

5. The electronic device of claim 1, wherein the insulator layer includes polybenzoxazole (PBO) material.

6. The electronic device of claim 1, wherein the insulator layer includes a solder mask material.

7. The electronic device of claim 1, further comprising a solder structure attached to the second conductive routing structure and extending outward from a bottom side of the electronic device.

8. The electronic device of claim 1, wherein the semiconductor substrate comprises a sensing area exposed along the first side of the semiconductor substrate and spaced apart from the first conductive routing structure.

9. An electronic device, comprising:
a semiconductor substrate having opposite first and second sides, a first conductive routing structure on the first side of the semiconductor substrate, and a via opening extending from the first side of the semiconductor substrate to the second side of the semiconductor substrate, a portion of the first conductive routing structure extending over the via opening;
a transparent cover over a portion of the first side of the semiconductor substrate, the transparent cover covering the patterned first conductive routing structure;
an insulator layer on the second side of the semiconductor substrate and along a sidewall of the via opening, the insulator layer including a polyimide material; and
a second conductive routing structure on an outer side of the insulator layer, the second conductive routing structure extending through the via opening and directly contacting the portion of the first conductive routing structure.

10. The electronic device of claim 9, wherein the semiconductor substrate has a thickness distance between the first and second sides approximately 20 μm or more and less than 150 μm.

11. The electronic device of claim 9, wherein the first and second conductive routing structures include copper.

12. The electronic device of claim 9, wherein the transparent cover includes glass.

13. The electronic device of claim 9, further comprising a solder structure attached to the second conductive routing structure and extending outward from a bottom side of the electronic device.

14. The electronic device of claim 9, wherein the semiconductor substrate comprises a sensing area exposed along the first side of the semiconductor substrate and spaced apart from the first conductive routing structure.

15. A method of fabricating an electronic device, the method comprising:
forming a patterned first conductive routing structure on a first side of a semiconductor substrate;
attaching a transparent cover over a portion of the first side of the semiconductor substrate, the transparent cover covering the patterned first conductive routing structure;
grinding a second side of the semiconductor substrate to reduce a thickness distance between the first and second sides to approximately 20 μm or more and less than 150 μm;
forming a via opening extending from the first side of the semiconductor substrate to the second side of the semiconductor substrate, a portion of the first conductive routing structure extending over the via opening;
forming an insulator layer on the second side of the semiconductor substrate and along a sidewall of the via opening; and
forming a second conductive routing structure on an outer side of the insulator layer, the second conductive routing structure extending through the via opening and directly contacting the portion of the first conductive routing structure.

16. The method of claim 15, wherein forming an insulator layer includes spin coating a photo-imageable material on the second side of the semiconductor substrate and along the sidewall of the via opening.

17. The method of claim 16, wherein forming an insulator layer further comprises patterning the photo-imageable material to expose a portion of the patterned first conductive routing structure in the via opening.

18. The method of claim 16, wherein the photo-imageable material includes polyimide material.

19. The method of claim 15, wherein the insulator layer includes polyimide material.

20. The method of claim 15, wherein the insulator layer includes polybenzoxazole material.

21. The method of claim 15, wherein the insulator layer includes a solder mask material.

22. The method of claim 15, further comprising:
forming a solder structure on the second conductive routing structure and extending outward from a bottom side of the electronic device.
